(19) United States
(12) Patent Application Publication
(10) Pub. No.: US 2012/0118371 A1
(43) Pub. Date: May 17, 2012

(54) LIGHT ELECTRON CONVERSION ELEMENT

(75) Inventors: Hironori Yoshida, Kanagawa (JP); Masashi Enomoto, Tokyo (JP); Toru Yatabe, Miyagi (JP); Masamitsu Kageyama, Miyagi (JP)

(73) Assignee: SONY CORPORATION, Tokyo (JP)

(21) Appl. No.: 13/278,722

(22) Filed: Oct. 21, 2011

(30) Foreign Application Priority Data
Nov. 12, 2010 (JP) 2010-253596

(51) Int. Cl. H01L 31/0224; H01L 31/0232; H01L 31/18

(52) U.S. Cl. 136/256; 438/57; 257/E31.124

(57) ABSTRACT

A photoelectric conversion element includes a substrate that has a first unevenness structure including a plurality of first convex portions on one principal surface and a second unevenness structure formed on a surface of the first unevenness structure and including a plurality of second convex portions. A light-receiving element is formed on the one principal surface of the substrate and includes a first electrode, a photoelectric conversion layer, and a second electrode in this order from the side of the substrate. At least the first electrode of the light-receiving element has a third unevenness structure replicated from one or both of the first and second unevenness structures on a surface opposite to the substrate.

### CROSS REFERENCES TO RELATED APPLICATIONS

The present application claims priority to Japanese Priority Patent Application JP 2010-253596 filed in the Japan Patent Office on Nov. 12, 2010, the entire content of which is hereby incorporated by reference.

### BACKGROUND

The present disclosure relates to a photoelectric conversion element and a method of manufacturing a photoelectric conversion element suitable for a solar battery using an organic compound.

In recent years, solar batteries serving as a power-generating apparatus realizing resource, saving, or cost reduction have come into practical use for various purposes. Silicon thin films are mainly used for the solar batteries. However, in recent years, CdTe-based or CIGS-based inorganic compounds or organic compounds such as high-molecular-weight polymers or low-molecular-weight polymers have drawn increasing attention as substitute materials for the silicon thin films. Further, dye-sensitized solar batteries have been developed. In particular, solar batteries (organic solar batteries) using an organic compound such as a polymer have been developed and studied for practical use since the solar batteries are easy in manufacture or allow cost reduction (for example, Japanese Unexamined Patent Application Publication No. 2009-278145).

In general, the above-mentioned solar batteries have a configuration in which a transparent electrode, a photoelectric conversion layer, and a reflection electrode are formed in this order on a transparent substrate such as glass. In such a configuration, light passing through the transparent substrate and being incident on the photoelectric conversion layer can be output as photo-electric current through the transparent electrode and the reflection electrode. In this way, the solar batteries convert the light energy of received sunlight or the like into electric energy for power generation.

### SUMMARY

The solar batteries such as organic solar batteries using an organic compound are excellent in terms of productivity. However, since materials used for an absorbed wavelength region are limited and element resistance is large, the generated current may not be output efficiently. Such organic solar batteries are expected to be applied in electric automobiles, and power generation efficiency has to be improved for mass production.

It is desirable to provide a photoelectric conversion element and a method of manufacturing the photoelectric conversion element capable of improving power generation efficiency.

According to an example embodiment of the disclosure, there is provided a photoelectric conversion element including a substrate that has a first unevenness structure including a plurality of first convex portions on one principal surface and a second unevenness structure formed on a surface of the first unevenness structure and including a plurality of second convex portions and a light-receiving element that is formed on the one principal surface of the substrate and includes a first electrode, a photoelectric conversion layer, and a second electrode in this order from the side of the substrate. At least the first electrode of the light-receiving element has a third unevenness structure replicated from one or both of the first and second unevenness structures on a surface opposite to the substrate.

According to another example embodiment of the disclosure, there is provided a method of manufacturing a photoelectric conversion element. The method includes forming a first unevenness structure including a plurality of first convex portions on one principal surface of a substrate and a second unevenness structure, which includes a plurality of second convex portions, on a surface of the first unevenness structure and forming a light-receiving element which includes a first electrode, a photoelectric conversion layer, and a second electrode in this order on the surface on which the first and second unevenness structures are formed. In the forming of the light-receiving element, a third unevenness structure replicated from one or both of the first and second unevenness structures is formed on at least a surface of the first electrode opposite to the substrate.

The photoelectric conversion element according to an example embodiment of the disclosure has the first unevenness structure including the plurality of first convex portions on the one principal surface of the substrate and the second unevenness structure including the plurality of second convex portions on the surface of the first unevenness structure. At least the first electrode of the light-receiving element has the third unevenness structure replicated from one or both of the first and second unevenness structures on the surface opposite to the substrate. Thus, the optical absorptance of the light-receiving element is improved and the current density is increased by the concentration of an electric field.

In the method of manufacturing the photoelectric conversion element according to an example embodiment of the disclosure, the first unevenness structure including the plurality of first convex portions and the second unevenness structure including the plurality of second convex portions are formed on the one principal surface of the substrate, and then the light-receiving element is formed on the one principal surface of the substrate. When the light-receiving element is formed, the third unevenness structure replicated from one or both of the first and second unevenness structures is formed on at least the surface of the first electrode opposite to the substrate.

In the photoelectric conversion element and the method of manufacturing the photoelectric conversion element according to the example embodiments, the first unevenness structure including the plurality of first convex portions and the second unevenness structure including the plurality of convex portions are formed on the one principal surface of the substrate. At least the first electrode of the light-receiving element has the third unevenness structure replicated from one or both of the first and second unevenness structures on the surface opposite to the substrate. Thus, the optical absorptance is improved and the generated current can be efficiently output. Accordingly, power generation efficiency can be improved.

Additional features and advantages are described herein, and will be apparent from the following Detailed Description and the figures.

### BRIEF DESCRIPTION OF THE FIGURES

FIG. 1 is a sectional view illustrating a solar battery according to an example embodiment of the disclosure.

FIG. 2 is a sectional view illustrating a stereoscopic structure on a substrate shown in FIG. 1.

FIG. 3A is an X-Y plan view illustrating a micro structure shown in FIG. 2 and FIG. 3B is a perspective view illustrating a convex portion.

FIG. 4A is an X-Y plan view illustrating a nanostructure shown in FIG. 2 and FIG. 4B is a perspective view illustrating a protrusion portion of the nanostructure.

FIGS. 5A to 5D are sectional views illustrating processes of manufacturing the substrate shown in FIG. 1.

FIG. 6 is a diagram illustrating an example of an apparatus that manufactures the substrate in a roll-to-roll manner.

FIG. 7 is a diagram illustrating an example of a method of manufacturing the substrate using a plate-shaped master.

FIG. 8 is a conceptual diagram illustrating the intensity and shape of a laser beam.

FIGS. 9A and 9B are diagrams illustrating a laser optical system when a form roll and a plate-shaped master are manufactured by laser processing.

FIG. 10 is a diagram illustrating current-voltage characteristic based on actual measurement values when convex portions of a pitch of 50 μm and 275 nm are formed on the surface of the substrate and when a flat plate is used.

FIG. 11 is a diagram illustrating photoelectric conversion efficiency expressed with a flat plate ratio.

FIG. 12 is a diagram illustrating a simulation result of optical absorptance (%) with respect to incident wavelength (nm) when the stereoscopic structure shown in FIG. 1 is used.

FIG. 13 is a diagram illustrating a ray tracing simulation result when light is incident on the flat plate.

FIG. 14 is a diagram illustrating a ray tracing simulation result of the microstructure shown in FIGS. 3A and 3B.

FIG. 15 is a diagram illustrating a correlation of respective light absorption amounts when the flat plate and a CCP are used.

FIG. 16 is a diagram illustrating a simulation result of the optical absorptances of the substrates with nanostructures with pitches of 275 nm and 150 nm and the flat plate.

FIG. 17 is a diagram illustrating a relationship between the resistance values of the substrates with nanostructures with a pitch of 275 nm and 150 nm and the flat plate and the reciprocal number of the pitch.

FIG. 18 is a diagram illustrating an equivalent circuit of a simulation model.

FIGS. 19A and 19B are diagrams illustrating the simulation result (current-voltage characteristic) of the equivalent circuit when the flat plate is used.

FIGS. 20A and 20B are diagrams illustrating the simulation result (current-voltage characteristic) of the equivalent circuit when the stereoscopic structure is used.

FIG. 21 is a diagram illustrating a TEM photo of an actually manufactured solar battery with the nanostructure.

FIG. 22A is an X-Y plan view illustrating a region corresponding to the convex portions with the microstructure in a stereoscopic structure according to Modified Example 1 and FIG. 22B is a perspective view illustrating the convex portion of the nanostructure.

FIG. 23 is a schematic view illustrating the substrate with a microstructure according to Modified Example 2.

FIG. 24A is an X-Y plan view illustrating a region corresponding to the convex portions with the microstructure in a stereoscopic structure according to Modified Example 2 and FIG. 24B is a perspective view illustrating the convex portion of the nanostructure.

FIG. 25A is an X-Y plan view illustrating a region corresponding to the convex portions with the microstructure in a stereoscopic structure according to Modified Example 3 and FIG. 25B is a perspective view illustrating the convex portion of the nanostructure.

FIG. 26 is a sectional view illustrating a solar battery according to another modified example.

FIGS. 27A to 27D are schematic views illustrating the configuration of a convex portion according to still another modified example.

### DETAILED DESCRIPTION

Embodiments of the present application will be described below in detail with reference to the drawings. The description thereof will be made in the following order.

1. Example Embodiment (Example of Organic Thin Film Solar Battery Having Hybrid Stereoscopic Structure of Microstructure (Multiple Reflection Structure) and Nanostructure (Protrusion Portions) on Surface of Substrate).

2. Modified Example 1 (Example of Microstructure (Multiple Reflection Structure) and Nanostructure (Moth-eye Structure)).

3. Modified Example 2 (Example of Microstructure (Protrusion Portions) and Nanostructure (Protrusion Portions)).

4. Modified Example 3 (Example of Microstructure (Protrusion Portions) and Nanostructure (Moth-eye Structure)).

5. Modified Example 4 (Example of Solar Battery Using Inorganic-based Material in Photoelectric Conversion Layer).

### Example Embodiment

### Configuration of Solar Battery 1

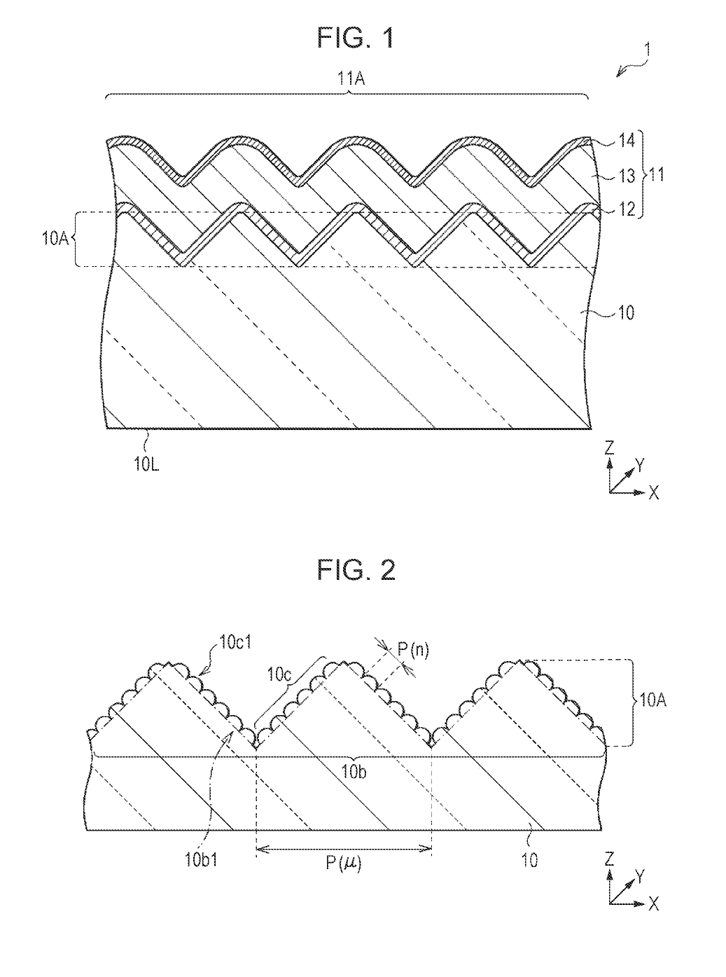

FIG. 1 is a sectional view illustrating the configuration of a solar battery 1 (photoelectric conversion element) according to an example embodiment of the disclosure. The solar battery 1 is a solar power generation element (organic thin film solar battery) performing photoelectric conversion using an organic compound thin film. The solar battery 1 includes a light-receiving element 11, for example, on the surface (one principal surface) of a substrate 10. The substrate 10 and the light-receiving element 11 come into contact with each other and the rear surface (opposite surface to the light-receiving element 11) of the substrate 10 serves as a light-incident surface 10L.

Substrate 10

The substrate 10 is made of a material, such as glass or plastic, transparent to light (absorbed light) incident on a photoelectric conversion layer 13 described below. The transmittance of the substrate 10 is preferably 70% or more of the light incident on the photoelectric conversion layer 13. Examples of the plastic suitably used for the substrate 10 include polyethylene terephthalate (PET), polyethylene naphthalate (PEN), polyimide, polycarbonate (PC), and COP (cycloolefin polymer). The substrate 10 preferably has rigidity (self-supporting property), but may have flexibility.

A stereoscopic structure 10A including a minute unevenness structure is formed on the surface (surface on the side of the light-receiving element 11) of the substrate 10. In FIG. 2, the detailed configuration of the stereoscopic structure 10A is shown. The stereoscopic structure 10A includes a microstructure 10b (first unevenness structure which is the entire structure indicated by a one-dot chain line) and a nanostructure 10c (second unevenness structure) formed on the surface of the microstructure 10b. In other words, in the stereoscopic structure 10A, the nanostructure 10c is superimposed on the microstructure 10b.

In the microstructure 10b, a plurality of convex portions 10b1 is two-dimensionally arranged at a pitch p(μ) of a micro-order on the surface of the substrate 10. The pitch p(μ) is preferably greater than 0.8 μm which is equal to or greater than the wavelength of visible light and is less than 250 μm and the height of the convex portion is set to a value appropriate for the size of the pitch. When the pitch of the convex portion 10b1 is greater than 250 μm, the film thickness necessary for the substrate 10 is thick. Thus, the flexibility is lost. By setting the pitch of the convex portion 10b1 to be less than 250 μm, the flexibility increases. Therefore, the convex portions can be manufactured easily in a roll-to-roll manner, and thus so-called batch manufacturing is unnecessary. Further, when the pitch is set to be in the range from 20 μm to 200 μm, the manufacturing is further improved.

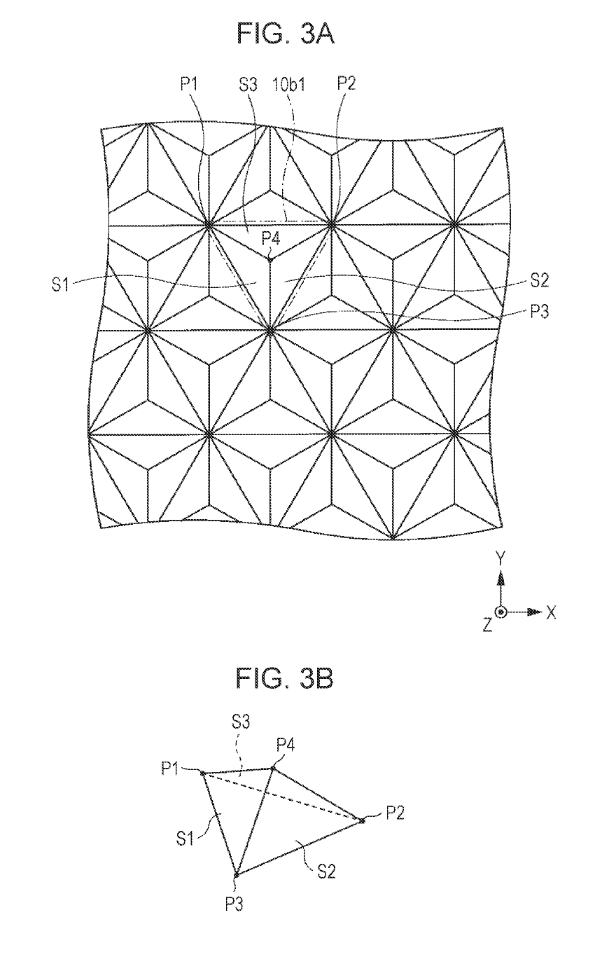

FIGS. 3A and 3B are diagrams illustrating the detailed configuration of the microstructure 10b. FIG. 3A is an X-Y plan view of the microstructure 10b and FIG. 3B is a perspective view of the convex portion 10b1. In the microstructure 10b according to this embodiment, the plurality of convex portions 10b1 is two-dimensionally arranged on an X-Y plan surface. For example, the convex portions 10b1 each have a triangular pyramid shape and are regularly carpeted on the surface of the substrate 10 without a gap. Specifically, in the convex portion 10b1, three surfaces S1, S2, and S3 other than the bottom surface serve as a reflection surface. Thus, the surfaces S1, S2, and S3 perform multiple reflection of light incident along a Z direction. Here, the convex portion 10b1 serves as a so-called Corner Cube Prism (CCP). Thus, the microstructure 10b1 has a multiple-reflection property.

The example has been described in which the plurality of convex portions 10b1 is two-dimensionally arranged on the surface of the substrate and each of the convex portions 10b1 serves as the CCP in the microstructure 10b. However, the convex portion is not limited thereto in this embodiment. Instead, the convex portion may be configured as a prism with another shape, for example, another pyramid such as a quadrangular pyramid or a cone or a columnar shape such as polygonal column or a circular cylinder.

In the nanostructure 10c, a plurality of protrusion portions 10c1 (second convex portions) is arranged at a pitch p(n) of a nano-order on the surface of the substrate 10. The pitch p(n) is preferably equal to or less than the wavelength order of visible light and is more preferably greater than 200 nm and equal to or less than 300 nm. In this embodiment, the plurality of convex portions 10c1 is regularly arranged at the pitch p(n)=275 nm. The height H of the convex portion 10c1 is in the range of, for example, 30 nm to 100 μm. An aspect ratio is preferably in the range of 0.2 to 2.0. This is because when the aspect ratio exceeds 2.0, it is difficult to laminate the light-receiving element 11 on the substrate 10. On the other hand, when the aspect ratio is less than 0.2, a variation in the refractive index is high in the interface between the substrate 10 and a transparent electrode 12 and in the vicinity of the interface, thereby increasing total reflectivity in the interface. When the aspect ratio is equal to or greater than 0.2, the total reflectivity is low, thereby increasing a ratio at which light incident from the light-incident surface 10L passes through the substrate 10 and the transparent electrode 12 and is incident on the photoelectric conversion layer 13.

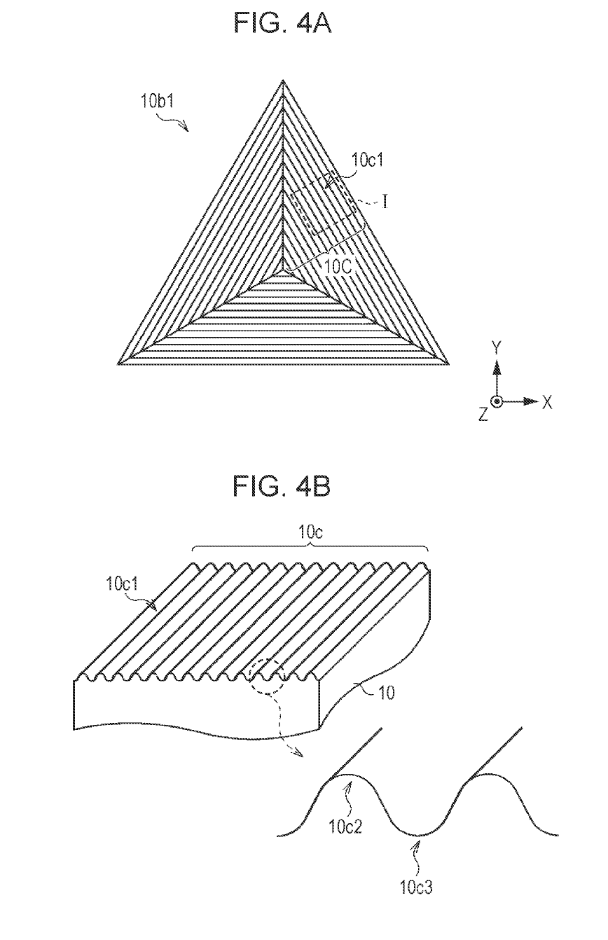

FIGS. 4A and 4B are diagrams illustrating the detailed configuration of the nanostructure 10c. FIG. 4A is an X-Y plan view of a region corresponding to one convex portion 10b1 and FIG. 4B is a perspective sectional view of a part (a part corresponding to a region I in FIG. 4A) of the nanostructure 10c. In the nanostructure 10c according to this example embodiment, the plurality of protrusion portions 10c1 extending in one direction is arranged in a direction perpendicular to the extension direction on the surface (the surface of the convex portion 10b1) of the microstructure 10b. Here, in the protrusion portions 10c1, a top portion 10c2 and a hollow portion 10c3 between two protrusion portions 10c1 adjacent to each other have a round shape. In this way, the top portion 10c2 of each protrusion portion 10c1 preferably has the round shape. This is because when the top portion 10c2 has a sharply pointed shape, a portion corresponding to the top portion 10c2 in the light-receiving element 11 is easily broken due to a coverage fault or the like. Further, as well as the top portion 10c2, the hollow portion between two protrusion portions 10c1 adjacent to each other more preferably has a round shape. That is, the nanostructure 10c overall has a wavy cross-sectional shape in the arrangement direction.

At least one of the top portion 10c2 and the hollow portion 10c3 may be formed in a flat shape. The surface of a part between the top portion 10c2 and the hollow portion 10c3 is preferably configured as an inclined surface, but may be configured as a vertical surface parallel to the lamination direction. The cross-sectional shape of the protrusion portion 10c1 may have, for example, a curved line shape such as a semi-circular shape or an elliptical shape or may have a polygonal shape such as a triangular shape or a trapezoidal shape. Further, all the protrusion portions 10c1 may not have the same shape. For example, the protrusion portions 10c1 having different shapes may be alternately arranged.

The light-receiving element 11 is an element that receives light incident from the side of the substrate 10 and outputs the energy of the received light as power. The light-receiving element 11 is disposed on the surface on which the stereoscopic structure 10A of the substrate 10 is formed. As shown in FIG. 1, the light-receiving element 11 includes, for example, the transparent electrode 12 (first electrode), the photoelectric conversion layer 13, and a reflection electrode 14 (second electrode) which are laminated in this order from the side of the substrate 10. Here, the entire light-receiving element 11, that is, the transparent electrode 12, the photoelectric conversion layer 13, and the reflection electrode 14 have a stereoscopic structure (referred to as a stereoscopic structure 11A) replicated from the stereoscopic structure 10A of the substrate 10.

Specifically, the stereoscopic structure 11A has a configuration replicated from one or both of the microstructure 10b and the nanostructure 10c in the stereoscopic structure 10A. For example, the stereoscopic structure 11A mainly has a shape replicated from the microstructure 10b (here, the multiple reflection structure shown in FIGS. 3A and 3B) (when viewed at a macro-level). The aspect ratio of the stereoscopic structure 11A is preferably the same as or smaller than the aspect ratio of the stereoscopic structure 10A in order to ensure the good coverage of the photoelectric conversion layer 13, the transparent electrode 12, and the reflection electrode 14. However, further, (when viewed in a micro-level), the stereoscopic structure 11A preferably has a plane shape of the nanostructure 10c (which is replicated from the wavy shape shown in FIGS. 4A and 4B).

The stereoscopic structure 11A may not necessarily be formed with the transparent electrode 12, the photoelectric conversion layer 13, and the reflection electrode 14. Instead, the stereoscopic structure 11A may be formed at least on the surface of the transparent electrode 12 opposite to the substrate 10. The stereoscopic structure 11A corresponds to a third unevenness structure according to the embodiment of the disclosure. The term “replicated” in the specification means that the respective stereoscopic structures are configured as substantially the same unevenness structure, but includes a case where the aspect ratios or the like of the respective convex portions are different from each other.

Transparent Electrode 12

The transparent electrode 12 is made of a transparent material with respect to the light received by the photoelectric conversion layer 13 and a material with conductivity. Examples of the material include ITO (Indium Tin Oxide), SnO (tin oxide), and IZO (Indium Zinc Oxide). The thickness of the transparent electrode 12 is in the range of, for example, 30 nm to 360 nm.

Photoelectric Conversion Layer 13

The photoelectric conversion layer 13 has a function of absorbing incident light and converting the energy of the absorbed light into power. The photoelectric conversion layer 13 is formed by laminating p-type and n-type conductive polymers (not shown) forming a pn junction. Specifically, the photoelectric conversion layer 13 is formed by laminating CuPc (copper phthalocyanine) as the p-type conductive film, a CuPc:C₆₀ film (co-evaporated film of copper phthalocyanine and fullerene), C₆₀ (fullerene) as the n-type conductive film, and BCP (bathocuproine) in this order from the side of the transparent electrode 12. For example, the thickness of the photoelectric conversion layer 13 is equal to or less than 100 nm. For example, LiF (lithium fluoride) and AlSiCu may be laminated on the photoelectric conversion layer 13. Further, LiF serving as a protective layer may be laminated on AlSiCu.

The material of the photoelectric conversion layer 13 is not limited to the above-mentioned materials, but may be an organic compound such as other polymers.

The photoelectric conversion layer 13 is formed on the surface of the transparent electrode 12. That is, the surface of the photoelectric conversion layer 13 on the side of the transparent electrode 12 has the stereoscopic structure 11A mainly replicated from the stereoscopic structure 10A. Thus, the surface area per unit area in the photoelectric conversion layer 13 when viewed in the lamination direction is larger compared to a case where the photoelectric conversion layer 13 is formed on a flat surface. Further, the photoelectric conversion layer 13 may be formed on the entire surface of the transparent electrode 12 or may be distributed in a pattern shape. The pattern shape is not particularly limited, but various shapes such as a mass shape or stripe shape may be used.

Reflection Electrode 14

The reflection electrode 14 contains at least one of materials, such as aluminum (Al), silver (Ag), platinum (Pt), gold (Au), chromium (Cr), tungsten (W), and nickel (Ni), which reflect light incident on the photoelectric conversion layer 13. Since the reflection electrode 14 is formed on the surface (wavy surface) of the photoelectric conversion layer 13, the reflection electrode 14 has a structure (the stereoscopic structure 11A) mainly replicated from the stereoscopic structure 10A on the surface opposite to the substrate 10. A layer made of lithium fluoride (LiF) or the like is preferably formed on the surface of the reflection electrode 14 on the side of the photoelectric conversion layer 13 (for example, between the layer made of BCP and the reflection electrode 14).

Method of Manufacturing Solar Battery 1

The above-described solar battery 1 is manufactured as follows, for example. That is, the substrate 10 having the stereoscopic structure 10A on its surface is manufactured, and then the transparent electrode 12 is formed on the surface (the surface on which the stereoscopic structure 10A is formed) of the substrate 10 in accordance with, for example, a sputter method. Subsequently, the photoelectric conversion layer 13 having the above-described lamination structure and the reflection electrode 14 are formed in this order on the formed transparent electrode 12 in accordance with, for example, a vacuum deposition method. Thus, the solar battery 1 shown in FIG. 1 is completed. Hereinafter, a specific example method of manufacturing the substrate 10 having the stereoscopic structure 10A will be described in detail with reference to the drawings.

Manufacturing Substrate 10

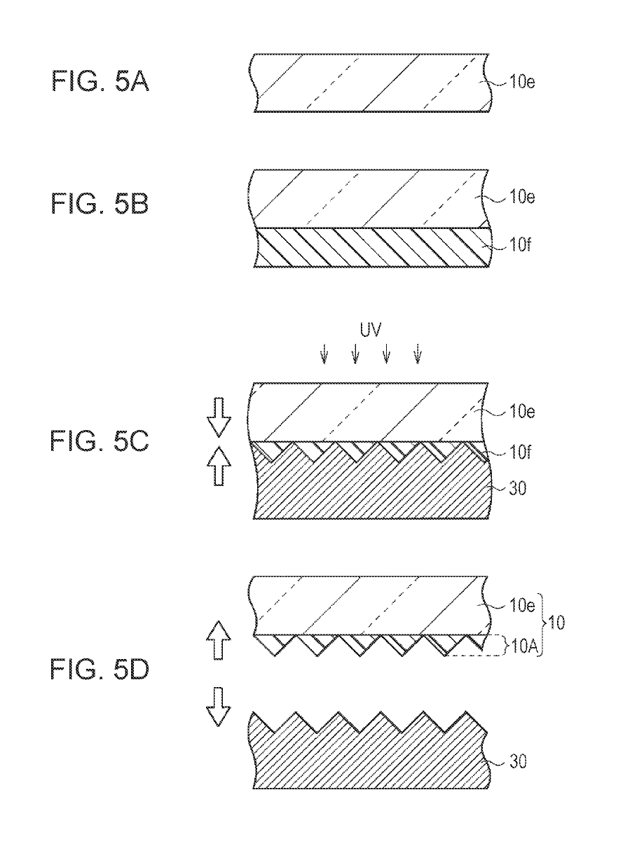

FIGS. 5A to 5D are diagrams illustrating the overview of the processes of manufacturing the substrate 10 of the solar battery 1. As shown in FIG. 5A, a basic substrate 10e of the substrate 10 is first prepared. Then, as shown in FIG. 5B, a resin layer 10f is applied on one surface of the basic substrate 10e. The above-described material (e.g. glass, plastic, or the like) of the substrate 10 is used as the basic substrate 10e and an ultraviolet curing resin or a heat curing resin is used as a resin layer 10f. Here, a case will be described in which the ultraviolet curing resin is used as the resin layer 10f. Subsequently, as shown in FIG. 5C, the form (master 30) having the reverse pattern of the unevenness of the stereoscopic structure 10A is tightly pressed against the surface of the formed resin layer 10f to cure the resin layer 10f, for example, by emitting ultraviolet light UV. Subsequently, as shown in FIG. 5D, the reverse pattern of the master 30 is transferred to the resin layer 10f by drawing and peeling the master 30 from the resin layer 10f. Here, the master 30 has the reverse pattern of the stereoscopic structure 10A including the microstructure 10b and the nanostructure 10c. A case will be described in which the microstructure 10b and the nanostructure 10c are transferred en bloc to the substrate 10 using the master 30.

The resin layer 10f may not necessarily be used and the reverse pattern of the master 30 may be directly transferred to the basic substrate 10e. Further, the basic substrate 10e and the resin layer 10f may come into direct contact with each other. For example, an anchor layer or the like may be installed between the basic substrate 10e and the resin layer 10f in order to improve adhesion.

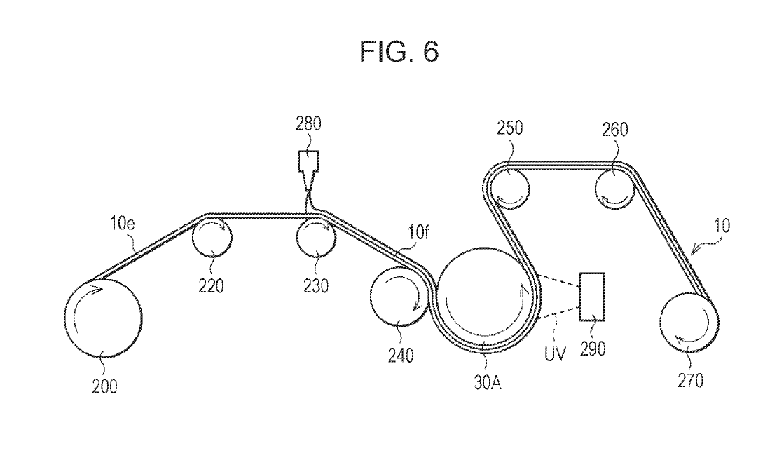

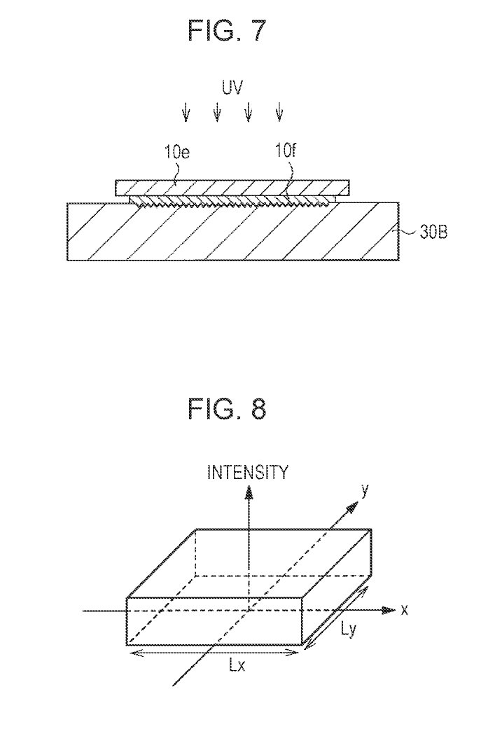

Subsequently, a specific example process of manufacturing the substrate 10 using the above-described master 30 will be described. For example, a roll-shaped master (form roll 30A) shown in FIG. 6 may be used as the master 30. For example, a flat plate-shaped master (plate-shaped master 30B) shown in FIG. 7 may be used as the master 30.

1. Case of Using Roll-Shaped Master

FIG. 6 is a diagram illustrating an example of an apparatus which forms a minute unevenness structure in a so-called roll-to-roll manner. In this case, the basic substrate 10e unwound from an unwinding roll 200 is first guided to a guided roll 230 via a guide roll 220. For example, the resin layer 10f is applied to the surface of the substrate 10e in the guide roll 230 by dropping an ultraviolet curing resin from, for example, an ejector 280. The resin layer 10f is pressed around the form roll 30A while tightly pressing a basic substrate 22a applied with the resin layer 10f by a nip roll 240.

Subsequently, the resin layer 10f is radiated with the ultraviolet light UV from an ultraviolet emitter 290 to cure the resin layer 10f. Here, a reverse pattern of a plurality of minute unevenness structures (the stereoscopic structure 10A including the microstructure 10b and the nanostructure 10c) is formed in advance on the circumferential surface of the form roll 30A. The reverse pattern of the form roll 30A is transferred to the resin layer 10f by tightly pressing the resin layer 10f against the circumferential surface of the form roll 30A and curing the resin layer 10f. Further, the ultraviolet emitter 290 is configured to emit the ultraviolet light UV toward a part of the basic substrate 10e coming into contact with the form roll 30A after the basic substrate 10e is supplied from the unwinding roll 200 and then passes though the nip roll 240.

Next, the basic substrate 10e and the resin layer 10f are detached from the form roll 30A by the guide roll 250, and then are wound by a winding roll 270 via a guide roll 260. In this way, the substrate 10 having the stereoscopic structure 10A on the surface can be manufactured. The method of using the roll-shaped master in the roll-to-roll manner is excellent in mass production.

When the substrate 10 is manufactured in the roll-to-roll manner, the material of the basic substrate 10e is preferably made of a film-shaped material or a sheet-shaped material with flexibility. Examples of the material include polyethylene terephthalate, polyethylene naphthalate, polycarbonate, polyimide, and COP. Here, for example, Zeonor or Zeonex (registered trademark of Zeon Inc.) may be used as COP.

Materials having flexibility other than the above resin materials may be used for the basic substrate 10e. When the basic substrate 10e is formed of a material of not transmitting ultraviolet light, the form roll 30A may be formed of a material (for example, quartz) transmitting ultraviolet light so that ultraviolet light can be emitted to the resin layer 10f from the inner side of the form roll 210. Further, when the heat curing resin is used as the resin layer 10f, a heater or the like may be provided instead of the ultraviolet emitter 290.

2. Case of Using Plate-Shaped Master

When the plate-shaped master 30A is used, the resin layer 10f is formed on the basic substrate 10e, as described above, and the resin layer 10f is cured by tightly pressing the plate-shaped master 30A against the resin layer 10f and emitting the ultraviolet light UV. Subsequently, the stereoscopic structure 10A is formed by peeling the plate-shaped master 30B from the resin layer 10f. Alternatively, the resin layer 10f may be applied directly to the surface of the plate-shaped master 30A, and then the basic substrate 10e is tightly pressed from the resin layer 10f so as to cure the resin layer 10f. Further, the pattern of the plate-shaped master 30A may be transferred directly to the basic substrate 10e without forming the resin layer 10f. When the plate-shaped master 30A is used, a material (glass, quartz, sapphire, silicon, or the like) having rigidity may be used for the basic substrate 10e in addition to the flexible material used in the roll-to-roll case.

Manufacturing of Master 30

Next an example method of manufacturing the above-described master 30 (the form roll 30A and the plate-shaped master 30B) will be described. The master 30 is formed by forming the reverse pattern of the stereoscopic structure 10A on the surface of a base roll (mother roll) made of a metal material such as NiP, Cu or stainless steel, quartz, silicon, silicon carbide, sapphire, or the like in accordance with the following method. That is, examples of the method of manufacturing the master 30 include methods of (A) bite cutting, (B) photolithography, (C) laser processing, (D) processing by abrasive grain, and (E) replica forming.

In this example embodiment, the stereoscopic structure 10A is a minute unevenness structure. In particular, in the nanostructure 10c, the pitch of the protrusion portions 10c1 is a nano-order such as 200 nm to 300 nm. When the minute unevenness structure is formed, an appropriate method of manufacturing the master is different depending on the pitch of the unevenness pattern. That is, when an unevenness pattern (a pattern corresponding to the microstructure 10b or the like) of a relatively large pitch is formed, bite cutting is preferably used. On the other hand, when an unevenness pattern (a pattern corresponding to the nanostructure 10c) of a relatively small pitch is formed, laser processing is preferably used. When the laser processing is used, the size of the pitch depends on the wavelength of a laser beam.

For example, the master 30 having the reverse pattern of the stereoscopic structure 10A may be formed as follows. First, the unevenness pattern corresponding to the microstructure 10A is formed on the surface of the base roll of the master 30 by the bite cutting. Subsequently, the pattern corresponding to the nanostructure 10c is formed on the surface of the unevenness pattern corresponding to the microstructure 10b by the laser processing. In this way, the master 30 having the unevenness pattern corresponding to the stereoscopic structure 10A is manufactured. Further, the methods of manufacturing the microstructure 10b and the nanostructure 10c are not limited to the bite cutting or the laser processing, for example, various methods described below may be used.

A. Bite Cutting

The unevenness pattern of the master 30 is subjected to cutting processing by the use of, for example, a single crystal diamond bite or a hard metal tool. In this method, the unevenness pattern can be formed at a pitch of a few hundreds of nm to a few hundreds of μm by cutting the surface (for example, a Ni—P plated surface) of the base roll with a bite. When the unevenness pattern formed by the bite cutting is viewed with an AFM (Atom Force Microscope), it is confirmed that grooves with a pitch of 275 nm are formed.

B. Photolithography

The unevenness pattern of the master 30 is formed by photolithography using, for example, an electron beam method or a two-beam interference method. When the electron beam method is used, a photoresist is applied on the surface of the base roll, a pattern is drawn by emitting an electron beam via a photomask, and a development process, an etching process, and the like are performed to form a desired pattern. On the other hand, when the two-beam interference method is used, an interference pattern is generated by interfering and emitting two laser beams and a pattern is formed using the interference pattern by lithography.

The photolithography can be used to manufacture a master having a pattern of a minute size (narrow pitch), such as a 150 nm pitch, at which it is difficult to manufacture the master by bite cutting. When the unevenness pattern formed by the photolithography is viewed with the AFM, it is confirmed that grooves with a pitch of 150 nm are formed.

C. Laser Processing

When the laser processing is used, the basic roll is formed using, for example, SUS, Ni, Cu, Al, or Fe and an unevenness pattern is drawn on the surface of the base roll using an ultrashort pulsed-laser, that is, a so-called femtosecond laser with a pulse width of 1 picosecond (10⁻¹² seconds) or less. At this time, an evenness pattern having a desired pitch and a desired aspect ratio can be formed by appropriately setting a laser wavelength, a repetition frequency, a pulse width, a beam spot shape, a type of light polarization, the intensity of a laser emitted to a sample, a scanning speed of the laser, and the like.

Specifically, the laser wavelength used for processing is, for example, 800 nm, 400 nm, or 266 nm. The repetition frequency is preferably large in consideration of processing time. For example, the repetition frequency may be 1000 Hz or 2000 Hz. The pulse width is preferably short. The pulse width is preferably in the range from about 200 femtoseconds (10⁻¹⁵ second) to about 1 picosecond (10⁻¹² second). The spot shape of the laser beam emitted to the form is, for example, a rectangular shape. Further, the beam spot can be formed by, for example, an aperture or a cylindrical lens. The intensity distribution of the beam spot is preferably as uniform as possible, for example, as shown in FIG. 8. This is because the depths of the grooves formed in the master 30 are uniform in the plane. On the assumption that the scanning direction of a laser is a y direction, Lx of the size (Lx, Ly) of the beam spot is determined depending on the width of a concave portion (or a convex portion) desired to be processed.

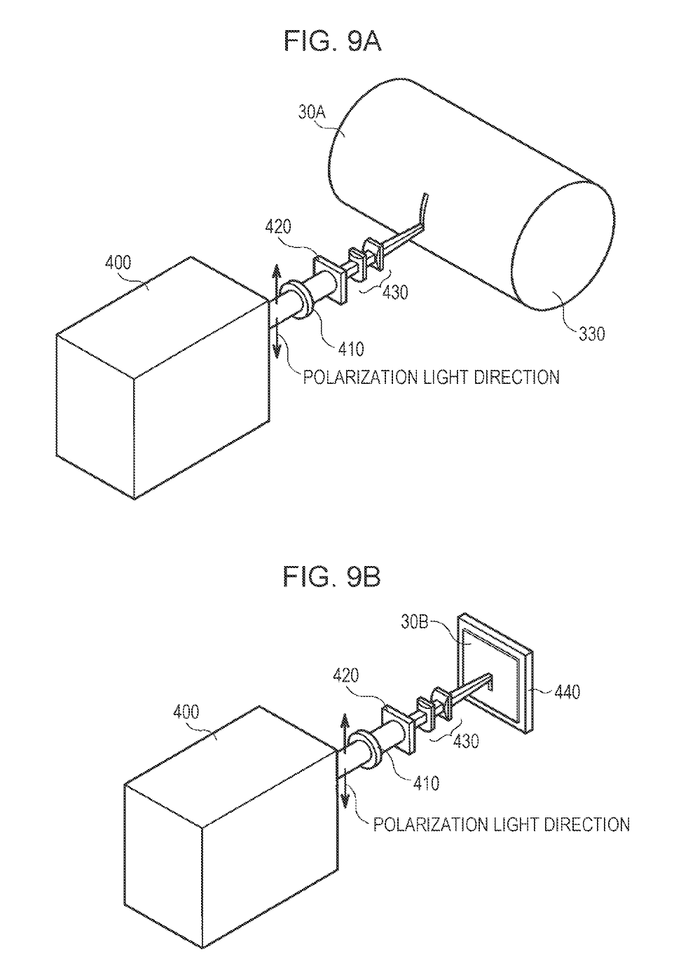

FIGS. 9A and 9B are diagrams illustrating examples of optical arrangements used for the laser processing. FIG. 9A shows the example in which the form roll 30A is manufactured as the master 30. FIG. 9B shows the example in which the plate-shaped master 30B is manufactured as the master 30. In both of the cases, a laser body 400, a wavelength plate 410, an aperture 420, and a cylindrical lens 430 are disposed along an optical axis. Thus, light emitted from the laser body 400 passes through the wavelength plate 410, the aperture 420, and the cylindrical lens 430 in sequence and is emitted to the master 30 to be radiated with the light.

The laser body 400 is, for example, IFRIT (product name: manufactured by Cyber Laser, Inc.). For example, the laser body 400 is configured to emit a linearly-polarized laser beam in a vertical direction. The laser wavelength is 800 nm, the repetition frequency is 1000 Hz, and the pulse width is 220 fs. The wavelength plate 410 (λ/2 wavelength plate) rotates the above laser beam in a polarization direction to convert the laser beam into a linearly polarized beam of a desired direction. The aperture 420 has a rectangular opening and takes out a part of the laser. Since the intensity distribution of the laser beam has a Gauss distribution, an in-plane intensity distribution of the emitted light can be made uniform. The cylindrical lens 430 is configured by two cylindrical lenses disposed so that axial directions in which refractive indexes are given are perpendicular to each other and forms a desired beam size by narrowing the laser beam.

In such an optical system, the laser beam may be scanned on the form roll 30A by winding the base roll of the form roll 30A around the circumferential surface of a roll 330 and rotating the roll 330, when the form roll 30A is manufactured. On the other hand, when the plate-shaped master 30B is manufactured, the laser beam may be scanned on the plate-shaped master 30B, for example, by moving a linear stage 440 on which the base roll of the plate-shaped master 30 is mounted at a constant speed. The embodiment of the disclosure is not limited to the rotation of the roll 330 and the movement of the linear stage 440. Conversely, the optical system may be rotated or moved from the laser beam 400 to the cylindrical lens 430.

The plurality (plurality of lines) of patterns can be formed en bloc through one emission of the laser by controlling the beam spot shape using the femtosecond laser. When the femtosecond laser is used, the grooves are formed so as to extend along a direction perpendicular to the polarization direction. Therefore, the direction of the grooves of the master 30 can be formed easily by the control of the polarized light. Accordingly, the manufacturing process can be simplified and it is easy to correspond to a case where the area of the master 30 is enlarged.

The unevenness pattern formed by the femtosecond laser has a desired periodic structure, but may have a structure (that is, a fluctuated periodic structure) slightly fluctuated in the period or the unevenness direction. In general, a pattern formed in accordance with other methods such as an electron beam drawing method has no fluctuation. When a pattern is transferred to the base roll using a form with the fluctuated pattern of the modified example, the fluctuated unevenness shape is also transferred to the base roll.

D. Processing by Abrasive Grain

The pattern of the master 30 can be formed using processing marks by fixed-abrasive grains or free abrasive grains. Specifically, when the form roll 30A is manufactured, a non-processed roll is rotated about its central axis and a circular plate grinding stone is rotated in a desired direction. At this time, alumina-based abrasive grains (grain with a granularity of about 1000 to 3000) is used as the abrasive grinding stone. The width of the grain surface of the grinding stone may be a width corresponding to the pitch of the pattern.

On the other hand, when the plate-shaped master 30B is manufactured, for example, a non-processed flat plate is slid in one direction and a circular plate grinding stone is rotated in a desired direction. At this time, an alumina-based abrasive grains (grain with a granularity of about 1000 to 3000) is used as the abrasive grinding stone. When the unevenness pattern formed in this way is viewed using the AFM, it is confirmed that the grooves with a pitch of a few hundreds of nm to a few hundreds of μm are formed in both of the plate shape and the roll shape.

E. Replica Forming

The pattern of the master 30 (here, the form roll 30A) may be formed by pressure-transferring of a form (master plate) having the unevenness pattern with the same unevenness shape as that of the pattern. That is, the form roll 30A is replicated (copied) from the master plate.

Specifically, the master plate with a roll shape with the unevenness pattern is first prepared. Subsequently, a non-processed form roll 30A (base roll) is rotated about its central axis and the master plate is rotated so that its central axis is parallel to the rotation axis of the base roll and the rotation speeds of the non-processed form roll and the master plate are the same as each other. Then, the unevenness pattern of the master plate is pressure-transferred by tightly pressing the master plate against the circumferential surface (non-ground region) of the base roll. When the unevenness pattern formed in this way is viewed with the AFM, it is confirmed that the convex portions of a pitch of a few hundreds nm to a few hundreds μm are formed. Further, when the form roll 30A is not used due to abrasion, a new form roll 30A can be manufactured from the master plate. Therefore, the substrate 10 having the stereoscopic structure 10A can be continuously manufactured. The form roll 30A may be manufactured from the master plate by so-called electroforming.

In this way, it is possible to easily form the substrate 10 having the stereoscopic structure 10A with the microstructure 10b and the nanostructure 10c by manufacturing the substrate 10 by the use of the master 30 manufactured in accordance with one of the above-described example methods (A) to (E).

In the above description, the example has been described in which the reverse patterns of the microstructure 10b and the nanostructure 10c are formed in the master 30 and the patterns are transferred to the substrate 10 en bloc as the method of forming the stereoscopic structure 10A. However, the following method may be used. That is, only the reverse pattern of the microstructure 10b is formed in the master 30 and the microstructure 10b is first formed in the substrate 10 by transferring by the use of the master 30. Thereafter, the nanostructure 10c may be formed directly on the surface of the formed microstructure 10b, for example, by laser processing. The type of laser used in this case, the processing condition, and the like can be set appropriately depending on the shape, size, or the like of the nanostructure 10c.

Operation and Advantage of Solar Battery 1

In the example embodiment, light (sunlight) incident from the light-incident surface 10L passes through the substrate 10, and then is received by the light-receiving element 11. In the light-receiving element 11, when the light passes through the transparent electrode 12 and is incident on the photoelectric conversion layer 13, conduction electrons increase by the energy of the incident light, and the holes and electrons are separated by a built-in electric field (pairs of hole and electron are generated). The charges generated in this way are output externally through the transparent electrode 12 and the reflection electrode 14, so that the photo-electric current is generated and electric power is generated.

In this embodiment, the stereoscopic structure 10A with the microstructure 10b and the nanostructure 10c is formed on the surface of the substrate 10 on the side of the transparent electrode 12. Further, each of the surfaces of the transparent electrode 12, the photoelectric conversion layer 13, and the reflection electrode 14 has the stereoscopic structure 11A replicated from the stereoscopic structure 10A (replicated from one or both of the microstructure 10b and the nanostructure 10c). When the photoelectric conversion layer 13 has the stereoscopic structure 11A, incident light is efficiently absorbed and current density increases by the concentration of an electric field in the photoelectric conversion layer 13, compared to a case where the surface of the substrate 10 is flat (the photoelectric conversion layer is flat).

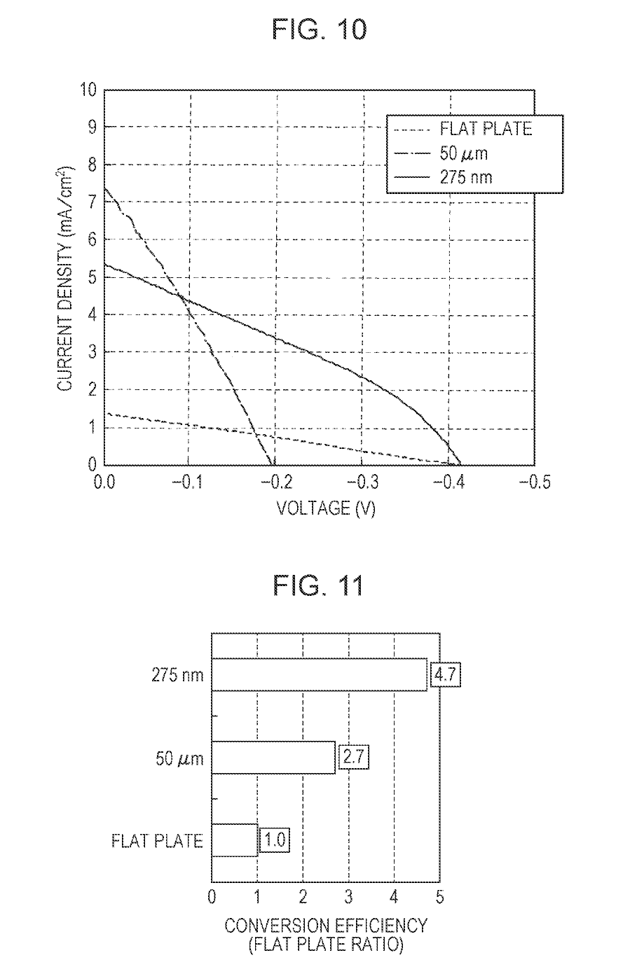

FIG. 10 is a diagram illustrating current-voltage characteristic (I-V characteristic) based on actually measured values when the convex portions are formed on the surface of the substrate 10 at a pitch of 50 μm and a pitch of 275 nm and when the convex portions are not formed (case of a flat plate). When the convex portions are formed, it can be understood that the current density (mA/cm²) for voltage (V) increases compared to the case of the flat plate. Further, when the pitch is 275 nm, the current density is about 3.8 times greater than the current density in the case of the flat pate. When the pitch is 50 μm, the current density is about 5.4 times greater than the current density in the case of the flat pate. When the pitch is 275 nm, the conversion efficiency is 4.7 times greater than the conversion efficiency in the case of the flat plate, as shown in FIG. 11. When the pitch is 50 μm, the conversion efficiency is 2.7 times greater than the conversion efficiency in the case of the flat plate. In consideration of these results, it is expected that the conversion efficiency is improved in both of the microstructure 10b having the micro-scale convex portions 10b1 and the nanostructure 10c having the nano-scale protrusion portions 10c1.

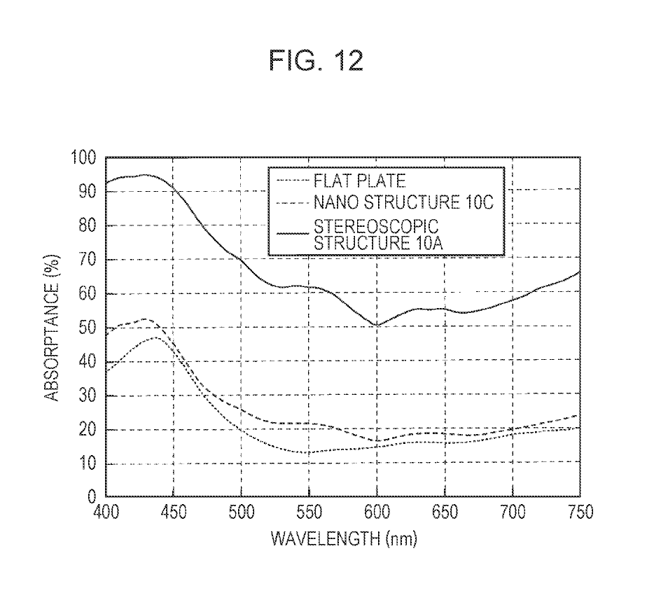

Here, FIG. 12 is a diagram illustrating a simulation result of optical absorptance (%) for the incident wavelength (nm) in the stereoscopic structure 10A which has the microstructure 10b and the nanostructure 10c according to the example embodiment. In the microstructure 10b of the stereoscopic structure 10A, the retro-reflection structure shown in FIGS. 3A and 3B is configured and the pitch of the convex portions 10b1 is set to 100 μm. On the other hand, in the nanostructure 10c, the plurality of protrusion portions 10c1 arranged at the pitch of 275 nm and its height of 90 nm is used, as shown in FIGS. 4A and 4B. As calculation methods, a ray tracing method (use software: LightTools (produced by CyberNet Inc.) is used for the microstructure 10b and the RCWA (Rigorous Coupled Wave Analysis) method (use software: DiffractMod (produced by RSoft Design Group Inc.) is used for the nanostructure 10c. In FIG. 12, the case of the flat plate and the case of only the nanostructure 10c are shown.

From the result, the optical absorptance of the stereoscopic structure 10A having both of the microstructure 10b and the nanostructure 10c is higher than those of the flat plate and only the nanostructure 10c. Specifically, the average of the optical absorptance of the stereoscopic structure 10A in the visible range is about 3.0 times greater than that of the flat plate. Further, the average of the optical absorptance of only the nanostructure 10c is about 1.2 times greater than that of the flat plate. Hereinafter, the operations of the microstructure 10b and the nanostructure 10c will be described.

Operation by Microstructure 10b

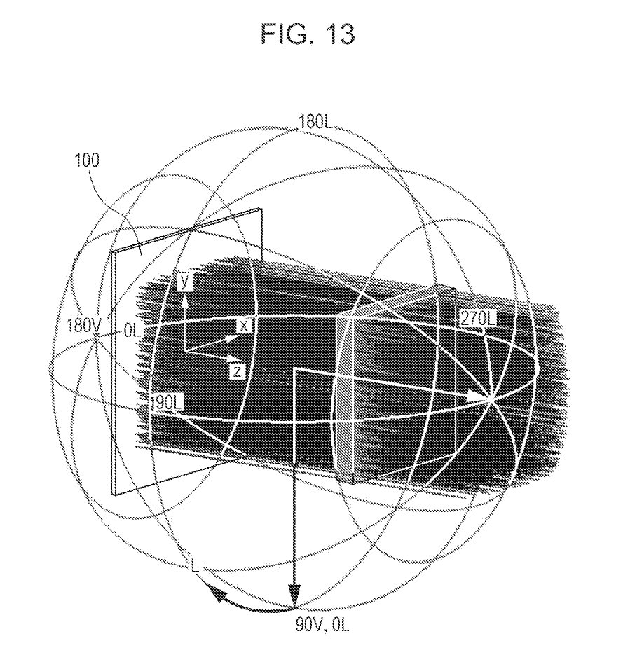

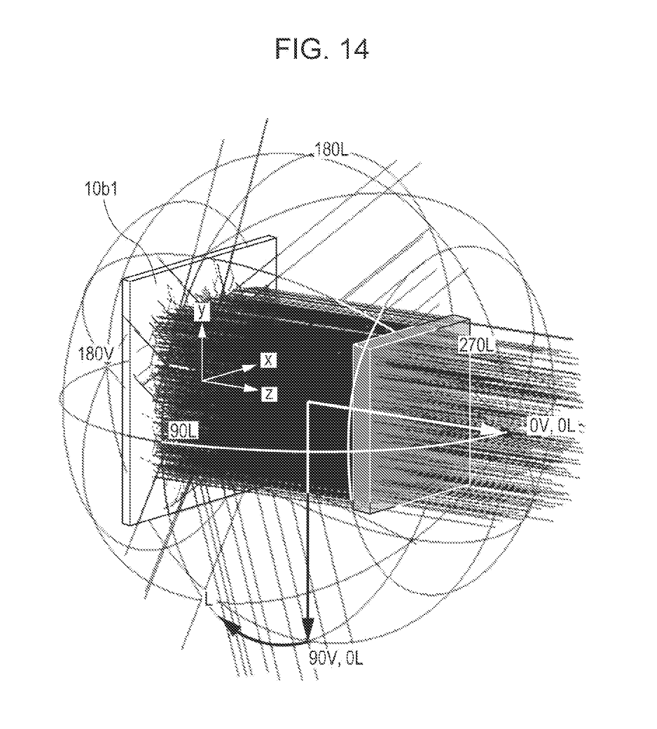

FIG. 13 is a diagram illustrating the result of a ray tracing simulation when light is incident on the flat plate (with no stereoscopic structure). FIG. 14 is a diagram illustrating the result of a ray tracing simulation of the microstructure 10b (the unevenness structure using the CCP) according to the example embodiment. When the flat plate is used, a light absorption amount is small (there is a lot of light not absorbed in the photoelectric conversion layer) since the number of times of reflection is only once. On the contrary, in the microstructure 10b using the CCP, the light absorption amount is larger than that of the flat plate since the number of times of incidence on the photoelectric conversion layer 13 increases due to multiple reflection.

FIG. 15 is a diagram illustrating correlation between the respective light absorption amounts when the flat plate and the CCP are used. In the simulation, there are used films A to C (conversion efficiency: A>B>C) of which photoelectric conversion efficiencies are different from each other. When the absorptance of the flat plate represented by the horizontal axis and the absorptance of the CCP represented by the vertical axis are plotted, the absorptance of the CCP is higher than that of the flat plate in all of the films A to C. Further, it can be understood that the advantage of improving the absorptance is noticeable for even a material with a relatively low photoelectric conversion efficiency (the advantage of improving the absorptance by the CCP: C>B>A).

Since the microstructure 10b including the plurality of convex portions 10b1 two-dimensionally arranged at the micro-order has the multiple reflection structure, the optical absorptance is improved in the photoelectric conversion layer 13. Accordingly, in the embodiment, the photoelectric conversion efficiency can be improved by the increase in the above-described current density (electrical advantage) and the improvement in the optical absorptance of the multiple reflection structure (optical advantage).

Operation of Nanostructure 10c

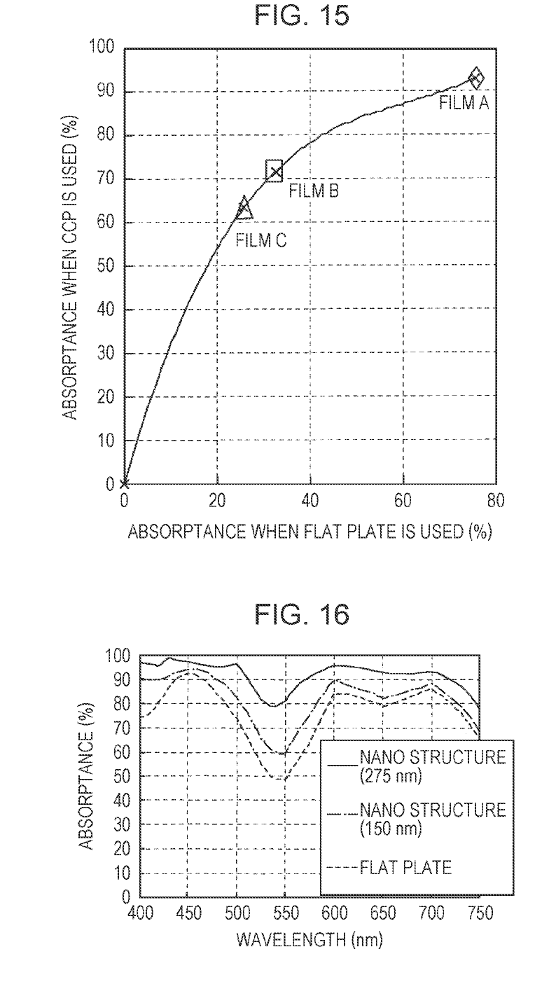

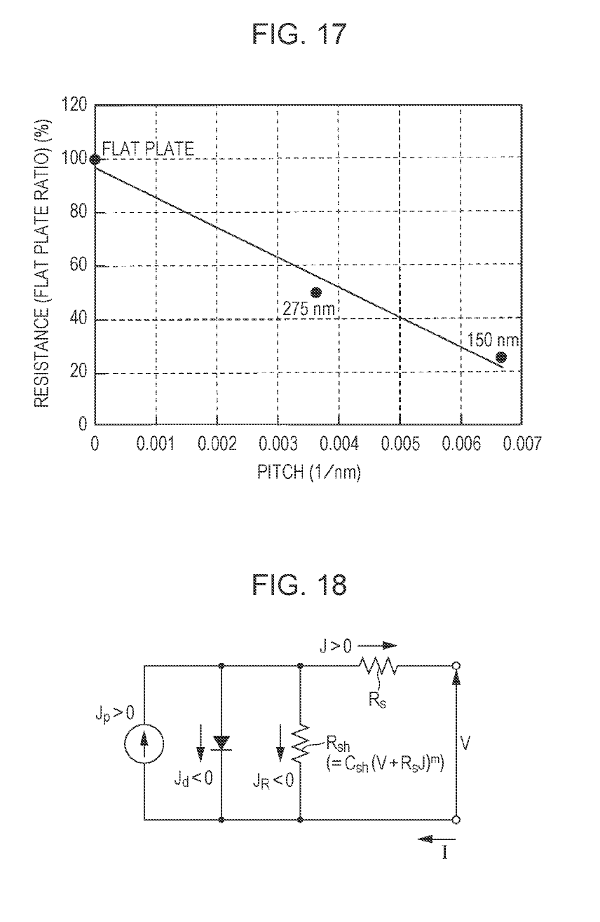

FIG. 16 is a diagram illustrating a simulation result of the optical absorptances of the substrate with only a nanostructure 10c with pitches of 275 nm and 150 nm and the flat plate. FIG. 17 is a diagram illustrating a relationship between the resistance values (actually measured values: ratios when the flat plate is set to 100%) in the photoelectric conversion layer (which is a C₆₀ fullerene layer shown below) of each structure and the reciprocal number of the pitch. When the resistance value is actually measured, a substrate is used in which an IZO layer (360 nm), a CuPc layer (30 nm), a C₆₀ layer (40 nm), a BCP layer (10 nm), a LiF layer (1 mm), an AlSiCu layer (100 nm), and a LiF layer (40 nm) subjected to oxygen plasma ashing are sequentially laminated on a quartz (SiO₂) substrate having the nanostructure 10c (with the pitch of 275 nm or 150 nm). The value of each parenthesis indicates the thickness of each layer. As an example of the flat plate, a plate is used in which an IZO layer (120 nm), a CuPc layer (30 nm), a C₆₀ layer (40 nm), a BCP layer (10 nm), a LiF layer (1 nm), an AlSiCu layer (100 nm), and a LiF layer (40 nm) subjected to oxygen plasma ashing are sequentially laminated on a flat plate-shaped glass substrate (AN100 (manufactured by Asahi Glass Co., Ltd.: product name)).

Thus, the resistance values of the elements having the nanostructure 10c (150 nm and 275 nm) are 25% and 50% of the resistance values of the flat plate, respectively.

A simulation is carried out with an equivalent circuit shown in FIG. 18 in order to theoretically analyze the result. In the equivalent circuit of the solar battery, the resistance component may be ignored and only a current supply (Jp) and a diode (which is not an ideal diode) may be taken into consideration as the simplest model. On the assumption that Jo is an opposite-direction saturated current, e is an elementary charge, V is a voltage, n is an ideal diode factor, k is the Boltzmann constant, and T is a temperature, the dark current J (current-voltage characteristic when no light is emitted) of the solar battery is expressed by Expression (1) below. Further, a series resistance Rₛ is a resistance component when a current flows in the element. Here, the dark current J=Jd.

$$\begin{matrix}J = - {J}_{0} \{ exp ( \frac{e ( V + {R}_{s} J )}{nkT} ) - 1 \} & ( 1 ) \\ J = {J}_{p} - {J}_{0} \{ exp ( \frac{e ( V + {R}_{s} J )}{nkT} ) - 1 \} - {{C}_{sh} ( V + {R}_{s} J )}^{m} & ( 2 )\end{matrix}$$

According to the Sah-Noyce-Shockley theory (n: an ideal diode factor depends on a position at which recombination of electrons and holes occurs), the idea is as follow.

When n=1, the recombination occurs in an n-type region and a p-type region (neutral region).

When n=2, the recombination occurs in a space-charge layer (depletion layer) via a recombination center of a band gap.

When n>2, the recombination occurs in other mechanisms (for example, tunnel effect).

When the photo-electric current is output by light radiation, approximation to an actual element is performed in consideration of both the series resistance Rₛ and a parallel resistance Rₛₕ. The series resistance Rₛ is a resistance element when a current flows in the above-described element. The capacity of the element is improved with a decrease in the series resistance. The capacity of the parallel resistance Rₛₕ is improved with an increase in the value of the parallel resistance, since a leak current or the like is generated near a pn junction. On the assumption that Cₛₕ is the capacity of a capacitor, the current-voltage characteristic is expressed by Expression (2) above at the light radiation to the solar battery including the resistance component.

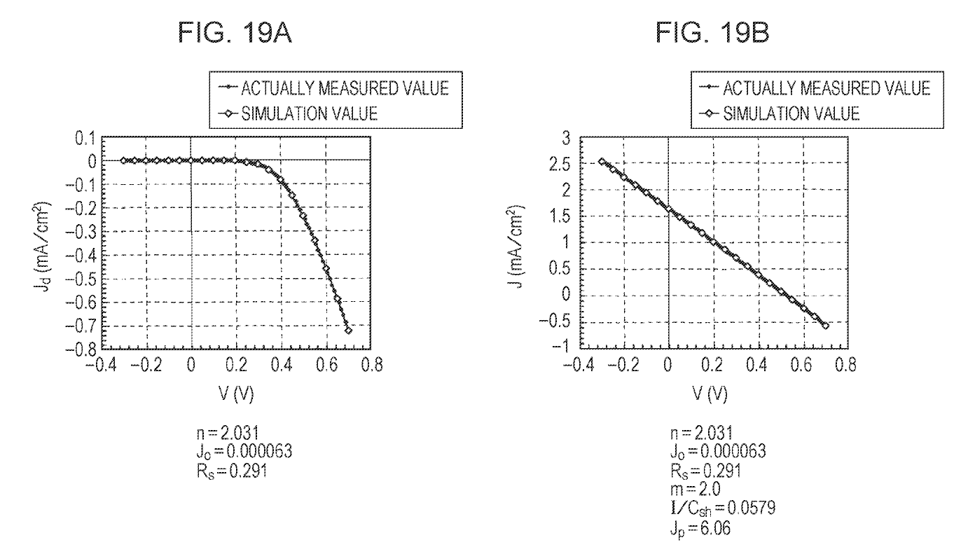

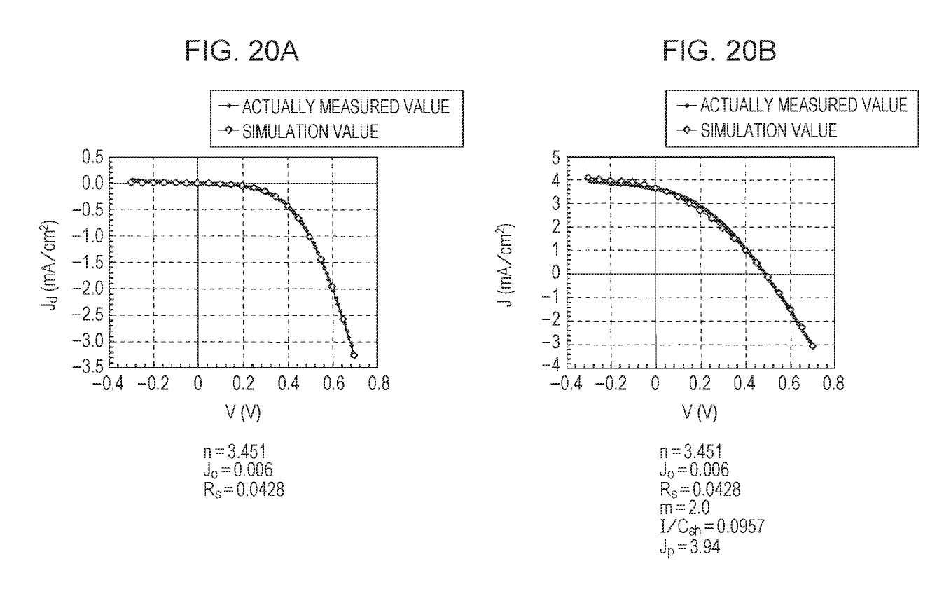

In the current-voltage characteristic of the equivalent circuit, as shown in FIGS. 19A and 19B and FIGS. 20A and 20B, the above-mentioned parameters are obtained by performing fitting so as to be substantially identical to the actually measured values. FIG. 19A is a diagram illustrating a case of no light radiation when the flat plate is used and FIG. 19B is a diagram illustrating a case of light radiation when the flat plate is used. FIG. 20A is a diagram illustrating a case of no light radiation when the nanostructure 10c (pitch of 150 nm) and FIG. 20B is a diagram illustrating a case of light radiation when the nanostructure 10c (pitch of 150 nm). When the nanostructure 10c is used, the series resistance Rₛ of the element is 0.0428×10⁻³ Ωcm². Therefore, it can be understood that the series resistance Rₛ is reduced by about 85% compared to the flat plate (0.291×10⁻³ Ωcm²). Thus, the current can be easily output from the solar battery. Further, the same element structure as that in the measurement of the resistance value shown in FIG. 17 is used at the actual measurement.

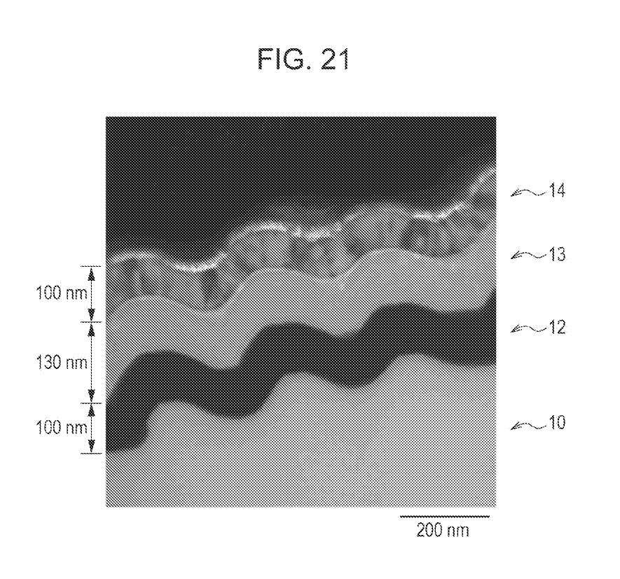

Accordingly, the current density can be efficiently increased in the nanostructure 10c in which the plurality of protrusion portions 10c1 is arranged at the nano-order. It is guessed that the advantage of increasing the current density is achieved from the decrease in the resistance of the entire element by the concentration of the electric field. As a consequence, the generated current can be efficiently output. Accordingly, in the embodiment, the conversion efficiency can be effectively increased due to an increase (electrical advantage) in the current density and an improvement in the optical absorptance by the nanostructure 10c. FIG. 21 is a diagram illustrating a TEM (Transmission Electron Microscope) photo of the nanostructure 10c. In the nanostructure 10c, the nano-scale unevenness structures are formed on the surface (the surface of the microstructure 10b) of the substrate 10. It can be understood that the transparent electrode 12, the photoelectric conversion layer 13, and the reflection electrode 14 have the surface shape replicated from the unevenness structure of the nanostructure 10c.

In this example embodiment, as described above, the surface of the substrate 10 has the stereoscopic structure 10A having the microstructure 10b and the nanostructure 10c. Therefore, the transparent electrode 12, the photoelectric conversion layer 13, and the reflection electrode 14 are formed in this order on the surface of the substrate 10 and each have the stereoscopic structure 11A replicated from the stereoscopic structure 10A. When the photoelectric conversion layer 13 has the stereoscopic structure 11A, the optical absorptance and the current density in the photoelectric conversion layer 13 can increase compared to the case where the surface of the substrate is flat (the photo electric conversion layer is flat). Accordingly, the photoelectric conversion efficiency can be improved particularly in a solar battery element such as an organic thin film solar battery.

When the microstructure 10b has the multiple reflection structure, the optical absorptance can increase. Further, when the nanostructure 10c is formed on the surface of the microstructure 10b, the current density can increase more efficiently.

Hereinafter, modified examples (Modified Examples 1 to 3) of the microstructure and the nanostructure of the above-described embodiment will be described. In the modified examples described below, the same reference numerals are given to the same constituent elements as those of the above-described embodiment and the description thereof will not be repeated.

### Modified Example 1

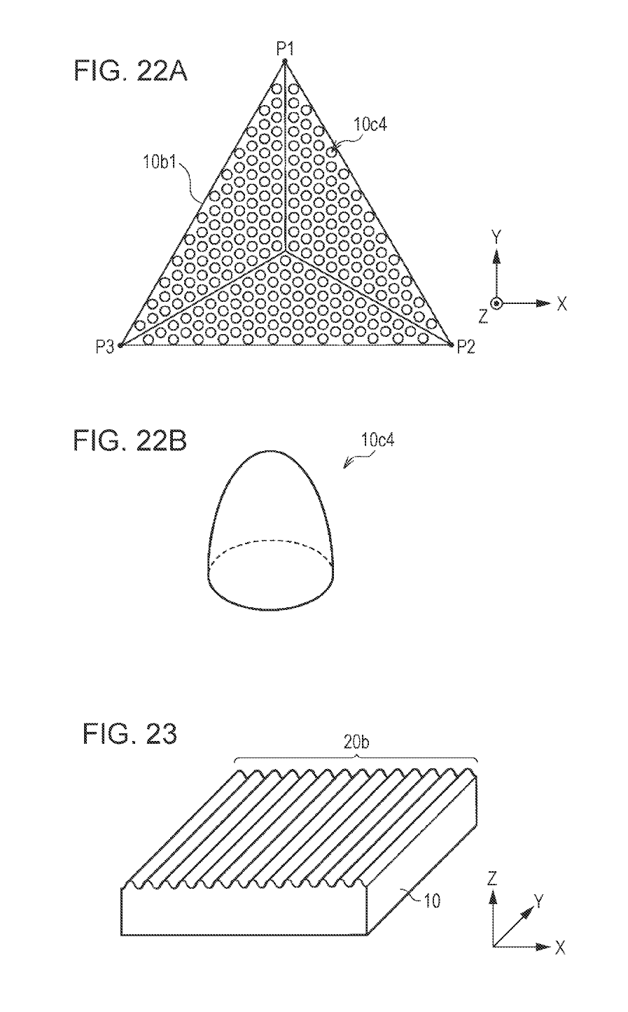

FIG. 22A is an X-Y plan view illustrating a region corresponding to one convex portion in the microstructure of the stereoscopic structure according to Modified Example 1 and FIG. 22B is a perspective view illustrating a convex portion (convex portion 10c4) in the nanostructure. In this modified example, as in the above-described embodiment, the microstructure 10b having the multiple reflection structure (for example, a retro-reflection structure) is formed in the stereoscopic structure formed on the surface of the substrate 10. The nanostructure is formed on the surface of the microstructure 10b. However, in this modified example, the nanostructure has a moth-eye structure in which the plurality of convex portions 10c4 is two-dimensionally arranged.

Specifically, the plurality of convex portions 10c4 with a hanging bell shape (of which a cross section is a semielliptical shape) is regularly arranged on the reflection surface of each convex portion 10b1 in the microstructure 10b. The pitch of the convex portions 10c4 is the nano-order and is preferably greater than 200 nm and equal to or less than 300 nm. The aspect ratio is preferably in the range of 0.6 to 1.2. It is because in the nanostructure (for example, a moth-eye structure) having a pitch equal to or greater than the wavelength order (for example, equal to or less than 800 nm) of the visible light, it is difficult to laminate the light-receiving element 11 on the substrate 10 when the aspect ratio exceeds 1.2. On the other hand, when the aspect ratio is less than 0.6, a variation in the refractive index is high in the interface between the substrate 10 and the transparent electrode 12 and in the vicinity of the interface, thereby increasing total reflectivity in the interface. When the aspect ratio is equal to or greater than 0.2, the total reflectivity is low, thereby increasing a ratio at which light incident from the light-incident surface 10L passes through the substrate 10 and the transparent electrode 12 and is incident on the photoelectric conversion layer 13.

In the modified example, the nanostructure may also use the moth-eye structure. Even in the case, the same advantage as that of the above-described embodiment can be obtained. When the effect of the Fresnel reflection is used by using the nanostructure in an element surface (interface between air and glass) of the solar battery, the optical absorptance can be improved in the light-receiving element, thereby generating a larger amount of power.

### Modified Example 2

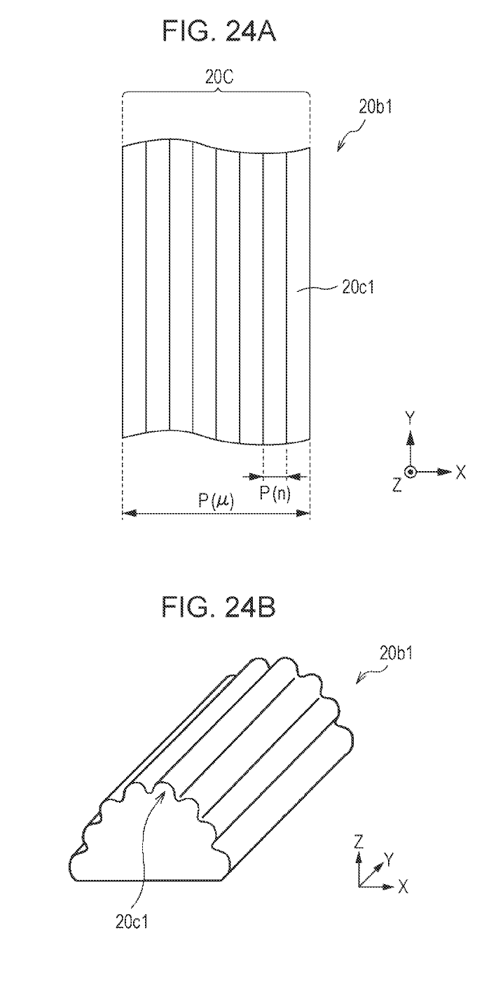

FIG. 23 is a schematic diagram illustrating the substrate 10 in a microstructure (microstructure 20b) according to Modified Example 2. FIG. 24A is an X-Y plan view illustrating a region corresponding to one convex portion (protrusion portion 20b1) in the microstructure 20b and FIG. 24B is a perspective view illustrating the region corresponding to one convex portion. In this example embodiment, in the stereoscopic structure on the surface of the substrate 10, the microstructure 20b in which the plurality of convex portions is arranged at a micro-scale pitch is formed, as in the above-described example embodiment. A nanostructure 20c is formed on the surface of the microstructure 20b. In this modified example, however, the microstructure 20b is configured by a plurality of protrusion portions 20b1 extending in one direction in the XY plane.

A nanostructure 20c is formed on the surface of each protrusion portion 20b1 and the nanostructure 20c is configured by a plurality of protrusion portions 20c1. For example, as shown in FIGS. 24A and 24B, the protrusion portions 20c1 in the nanostructure 20c extend in the same direction as that of the protrusion portion 20b1 and are arranged in a direction perpendicular to the direction.

In the microstructure of the stereoscopic structure on the surface of the substrate 10, even when the protrusion portion 20b1 extends in one direction, the same advantage as that of the above-described embodiment can be obtained.

Further, the extension direction of the protrusion portion 20c1 in the nanostructure 20c may not necessarily be the same as the extension direction of the protrusion portion 20b1 in the microstructure 20b. For example, these protrusion portions may extend in the directions perpendicular to each other.

### Modified Example 3

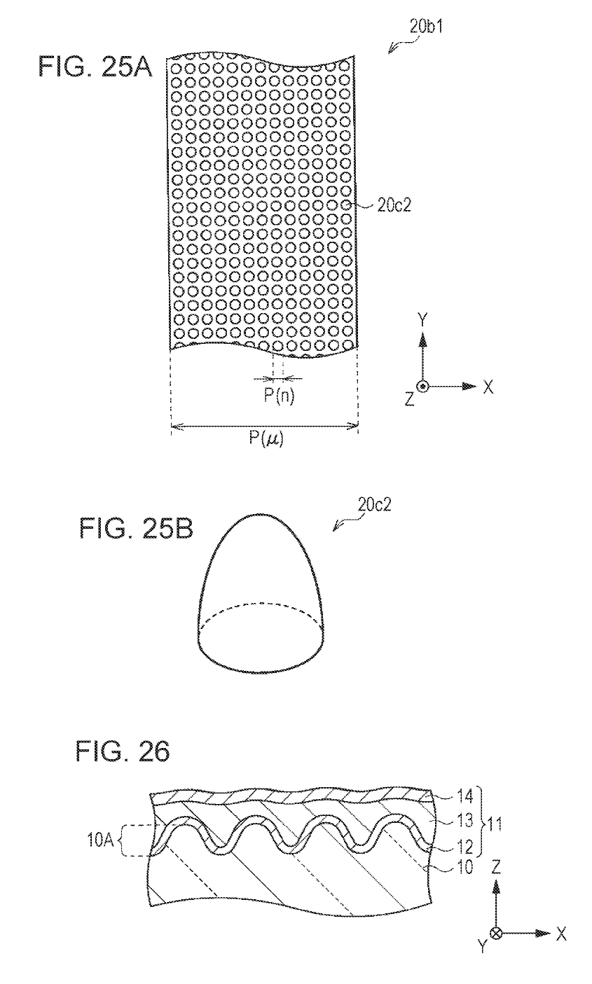

FIG. 25A is an X-Y plan view illustrating a region corresponding to one convex portion (protrusion portion 20b1) in the microstructure 20b and FIG. 25B is a perspective view illustrating one convex portion (protrusion portion 20c2) in the nanostructure. In this modified example, in the stereoscopic structure on the surface of the substrate 10, the microstructure 20b in which the plurality of convex portions is arranged at a micro-scale pitch is formed, as in the above-described example embodiment. A nanostructure is formed on the surface of the microstructure 20b. As in the above modified example, the microstructure 20b is configured by the plurality of protrusion portions 20b1 extending in one direction in the XY plane. In this modified example, however, the nanostructure has a so-called moth-eye structure in which a plurality of convex portions 20c2 is two-dimensionally arranged.

Specifically, the plurality of convex portions 20c2 with a hanging bell shape (of which a cross section is a semielliptical shape) is regularly arranged on the surface of each convex portion 20b1 in the microstructure 20b. Due to the same reason as that of Modified Example 1 described above, the pitch of the convex portions 20c2 is preferably greater than 200 nm and equal to or less than 300 nm. The aspect ratio is preferably in the range of 0.6 to 1.2.

Thus, the stereoscopic structure on the surface of the substrate 10 may have a configuration in which the microstructure 20b configured by the plurality of protrusion portions 20b1 and the nanostructure configured by the plurality of protrusion portions 20c2 are combined. In this case, the same advantage as that of the above-described embodiment can be obtained.

### Modified Example 4

In the above-described embodiment and the like, the organic thin film solar battery has been exemplified as the photoelectric conversion element according to the example embodiment of the disclosure. However, as in this modified example, a solar battery (for example, an amorphous silicon solar battery) using an inorganic-based material in the photoelectric conversion layer can be used. Specifically, a photoelectric conversion layer may be formed by laminating a p-type amorphous silicon film (for example, a film thickness of 13 nm), an i-type amorphous silicon film (for example, a film thickness of 250 nm), and an n-type amorphous silicon film (for example, a film thickness of 30 nm) in this order from the side of the substrate 10 having the above-described stereoscopic structure 10A. The photoelectric conversion layer can be formed by plasma CVD at a state where the substrate 10 is heated at 170° C. The configuration other than the photoelectric conversion layer is the same as that of the above-described embodiment.

However, the inorganic-based material of the photoelectric conversion layer is not limited to the above-mentioned materials. Further, the photoelectric conversion layer may be formed by a vapor-phase epitaxial method such as thermal CVD or a sputtering method as well as the plasma CVD. Furthermore, an organic compound such as other polymer may be contained in a part of the inorganic-based material.

The example embodiment and the modified examples of the disclosure have been described above, but the present disclosure is not limited thereto, and may be modified in various forms. For example, in the above-described example embodiment, under the influence of the stereoscopic structure 10A of the substrate 10, the large wavy shape is formed on the surfaces of the photoelectric conversion layer 13 and the reflection electrode 14 opposite to the substrate 10. However, as shown in FIG. 26, the surfaces of the photoelectric conversion layer 13 and the reflection electrode 14 may be formed mainly flat (e.g., gently wavy shape).

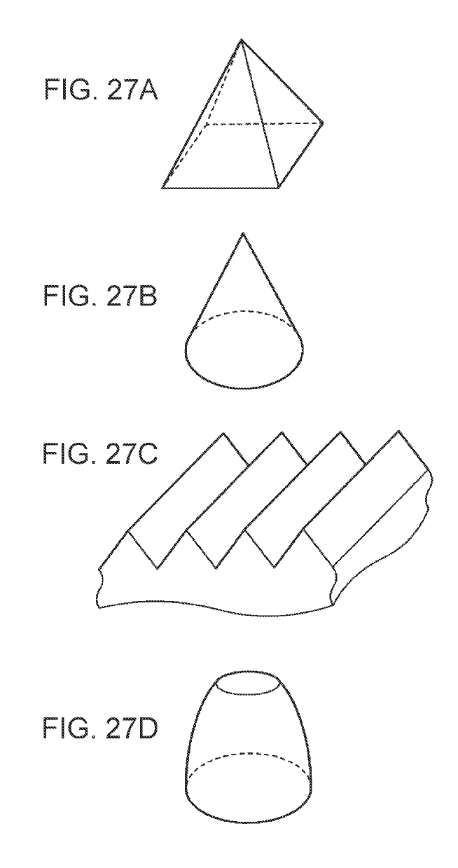

In the above-describe example embodiment and the like, the cases have been described above in which in the stereoscopic structure on the surface of the substrate 10, the convex portion of the microstructure has the triangular pyramid shape in the case of the CCP (example embodiment) or the round shape (Modified Examples 2 and 3). However, the shape and the arrangement of the convex portions in the microstructure are not limited thereto. For example, as shown in FIGS. 27A and 27B, pyramid-shaped prisms may be two-dimensionally arranged. As shown in FIG. 27C, a plurality of prisms with a polygonal column shape such as a cross-sectional triangle may be arranged. In the moth-eye structure, the convex portion with a hanging bell shape has been exemplified. However, the shape of each convex portion is not limited thereto. For example, as shown in FIG. 27D, the upper portion of each convex portion may have a chamfered shape (the top portion of a hanging bell has a flat surface).

In the above-describe embodiment and the like, the organic thin film solar battery has been exemplified as the photoelectric conversion element according to the example embodiment of the disclosure. Other solar battery elements such as a silicon hybrid-type solar battery using a silicon thin film (amorphous or fine crystal thin film) or an inorganic solar battery using a CdTe-based or CIGS-based inorganic compound may be used. However, in the CIGS-based solar battery, a reflection electrode serving as the first electrode, a photoelectric conversion layer, and a transparent electrode serving as the second electrode may be laminated in this order on the surface of a transparent substrate and light may be incident from the side of the transparent electrode. The example embodiment of the disclosure is applicable to, for example, a dye-sensitized solar battery and the resistance component can be reduced.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A photoelectric conversion element comprising:
a substrate that has a first unevenness structure including a plurality of first convex portions on one principal surface and a second unevenness structure formed on a surface of the first unevenness structure and including a plurality of second convex portions; and
a light-receiving element that is formed on the one principal surface of the substrate and includes a first electrode, a photoelectric conversion layer, and a second electrode in this order from the side of the substrate,
wherein at least the first electrode of the light-receiving element has a third unevenness structure replicated from at least one of the first and second unevenness structures on a surface opposite to the substrate.

2. The photoelectric conversion element according to claim 1, wherein the plurality of first convex portions of the first unevenness structure is two-dimensionally arranged on the one principal surface of the substrate.

3. The photoelectric conversion element according to claim 2, wherein the first unevenness structure has a multiple reflection structure.

4. The photoelectric conversion element according to claim 2, wherein the second unevenness structure includes protrusion portions as the second convex portions.

5. The photoelectric conversion element according to claim 2, wherein the plurality of second convex portions of the second unevenness structure is two-dimensionally arranged on the surface of the first unevenness structure.

6. The photoelectric conversion element according to claim 5, wherein the second unevenness structure has a moth-eye structure.

7. The photoelectric conversion element according to claim 1, wherein the first unevenness structure includes protrusion portions as the first convex portions.

8. The photoelectric conversion element according to claim 7, wherein the second unevenness structure includes protrusion portions as the second convex portions.

9. The photoelectric conversion element according to claim 7, wherein the plurality of second protrusion portions of the second unevenness structure is two-dimensionally arranged on the surface of the first unevenness structure.

10. The photoelectric conversion element according to claim 9, wherein the second unevenness structure has a moth-eye structure.

11. The photoelectric conversion element according to claim 1, wherein a pitch of the first convex portions is greater than 0.8 μm and less than 250 μm.

12. The photoelectric conversion element according to claim 1, wherein in the second unevenness structure, a pitch of the second convex portions is equal to or less than a wavelength order of visible light.

13. The photoelectric conversion element according to claim 12, wherein the pitch of the second convex portions is greater than 200 nm and equal to or less than 300 nm.

14. The photoelectric conversion element according to claim 1, wherein an aspect ratio of the second convex portions is in the range from 0.2 to 2.0.

15. The photoelectric conversion element according to claim 14,
wherein the second unevenness structure has a moth-eye structure, and
wherein the aspect ratio of the second convex portions is in the range from 0.6 to 1.2.

16. The photoelectric conversion element according to claim 1, wherein the photoelectric conversion element is an organic thin film solar battery.

17. A method of manufacturing a photoelectric conversion element, comprising:
forming a first unevenness structure including a plurality of first convex portions on one principal surface of a substrate and a second unevenness structure, which includes a plurality of second convex portions, on a surface of the first unevenness structure; and
forming a light-receiving element which includes a first electrode, a photoelectric conversion layer, and a second electrode in this order on the surface on which the first and second unevenness structures are formed,
wherein in the forming of the light-receiving element, a third unevenness structure replicated from at least one of the first and second unevenness structures is formed on at least a surface of the first electrode opposite to the substrate.

18. The method according to claim 17, wherein in the forming of the first and second unevenness structures, the first and second unevenness structures are formed en bloc on the one principal surface of the substrate by transferring a form which has an unevenness pattern corresponding to the first and second unevenness structures.

19. The method according to claim 17, wherein in the forming of the first and second unevenness structures, the first unevenness structures is formed on the one principal surface of the substrate by transferring a form which has an unevenness pattern corresponding to the first unevenness structure, and then the plurality of convex portions is formed on surfaces of the first convex portions of the first unevenness structure by laser processing.

20. The method according to claim 18, wherein the unevenness pattern of the form is formed by laser processing.
